(19) United States
(12) Patent Application Publication
(10) Pub. No.: US 2025/0038044 A1
(43) Pub. Date: Jan. 30, 2025

(54) MANAGING CONDUCTIVE CONNECTIONS FOR SEMICONDUCTIVE DEVICES

(71) Applicant: Yangtze Memory Technologies Co., Ltd., Wuhan (CN)

(72) Inventors: Yingcheng Zhao, Wuhan (CN); Liang Xiao, Wuhan (CN); Lina Miao, Wuhan (CN); Shu Wu, Wuhan (CN)

(21) Appl. No.: 18/459,398

(22) Filed: Aug. 31, 2023

Related U.S. Application Data
(63) Continuation of application No. PCT/CN2023/109046, filed on Jul. 25, 2023.

(51) Int. Cl. H01L 21/768; H01L 23/00; H01L 23/522; H01L 25/18; H10B 43/27; H10B 80/00; H01L 23/532

(52) U.S. Cl. CPC H01L 21/76816; H01L 21/76852; H01L 23/5226; H01L 24/02; H01L 24/05; H01L 24/08; H01L 24/09; H01L 25/18; H10B 43/27; H10B 80/00; H01L 21/76885; H01L 23/53214; H01L 23/53257; H01L 2224/02313; H01L 2224/02381; H01L 2224/0239; H01L 2224/05548; H01L 2224/05567; H01L 2224/05624; H01L 2224/05684; H01L 2224/08145; H01L 2224/09181; H01L 2924/01013; H01L 2924/01074; H01L 2924/1431; H01L 2924/14511

(57) ABSTRACT

Systems, devices, and methods for managing conductive connections for semiconductor devices are provided. In one aspect, a method includes: providing an integrated structure including an array structure in a first region and a conductive connection structure in a second region adjacent to the first region, at least one portion of at least one polysilicon layer being over the conductive connection structure; etching the at least one portion of the at least one polysilicon layer to expose one or more conductive connections in the conductive connection structure; depositing an isolating material over the array structure and the conductive connection structure; and forming conductive vertical interconnect accesses (VIAs) through the isolating material to be in contact with the one or more conductive connections and a conductive layer in the array structure.

### CROSS-REFERENCE TO RELATED APPLICATIONS

This application is a continuation of International Application No. PCT/CN2023/109046, filed on Jul. 25, 2023, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. However, as more layers are stacked in a same area, it can be challenging to manage conductive connections among different components and/or with external devices or components.

### SUMMARY

The present disclosure describes methods, devices, systems and techniques for managing conductive connections for semiconductor devices, e.g., 3D memory devices.

One aspect of the present disclosure features a method including: providing an integrated structure including an array structure in a first region and a conductive connection structure in a second region adjacent to the first region, at least one portion of at least one polysilicon layer being over the conductive connection structure; etching the at least one portion of the at least one polysilicon layer to expose one or more conductive connections in the conductive connection structure; depositing an isolating material over the array structure and the conductive connection structure; and forming conductive vertical interconnect accesses (VIAs) through the isolating material to be in contact with the one or more conductive connections and a conductive layer in the array structure.

In some embodiments, forming the conductive VIAs includes: etching the isolating material to expose the one or more conductive connections in the conductive connection structure together with a portion of the conductive layer in the array structure; and depositing a conductive material on the one or more conductive connections in the conductive connection structure and the portion of the conductive layer in the array structure to form the conductive VIAs, where each of the conductive VIAs is coupled to a corresponding one of the one or more conductive connections and the portion of the conductive layer.

In some embodiments, the one or more conductive connections in the conductive connection structure and the portion of the conductive layer in the array structure are exposed together during etching the isolating material.

In some embodiments, the method further includes: depositing a conductive pad layer on the conducive VIAs; depositing at least one cover layer over the conductive pad layer; and forming one or more pad openings through the at least one cover layer to expose one or more corresponding portions of the conductive pad layer.

In some embodiments, the method further includes: depositing a dielectric layer on the conductive pad layer, the dielectric layer being between the conductive pad layer and the at least one cover layer. Forming the one or more pad openings can include: etching through the at least one cover layer and the dielectric layer to form the corresponding pad openings.

In some embodiments, the conductive pad layer includes a first conductive material, and the conductive VIAs include a second conductive material different from the first conductive material.

In some embodiments, the conductive VIAs and the conductive pad layer are formed in a same process by depositing a same conductive material.

In some embodiments, the at least one polysilicon layer includes multiple portions, and where the at least one portion of the at least one polysilicon layer is a first portion of the at least one polysilicon layer, and a second portion of the at least one polysilicon layer is over the array structure. Providing the integrated structure can include: etching the second portion of the at least one polysilicon layer to expose a plurality of strings of memory cells and a gate line between adjacent groups of strings in the array structure; and forming the conductive layer across the first region, where the conductive layer is in contact with end surfaces of the plurality of strings of memory cells and the gate line.

In some embodiments, the end surfaces of the plurality of strings of memory cells and the gate line form an even surface. In some embodiments, the end surfaces of the plurality of strings of memory cells and the gate line form an uneven surface.

In some embodiments, forming the conductive VIAs includes: forming a conductive VIA through the isolating material to be in contact with a portion of the conductive layer that is over the gate line.

In some embodiments, etching the at least one portion of the at least one polysilicon layer includes: etching an entirety of the at least one portion of the at least one polysilicon layer within an etching region. The first region and the second region can be arranged along a first direction, and the one or more conductive connections can extend along a second direction perpendicular to the first direction. The etching region can have first and second opposite edges along the first direction, the first edge being extendable to an edge of a plane for the integrated structure, the second edge being extendable to an edge of the second region. The etching region can have an etching depth from a top surface to a bottom surface along the second direction, a distance between the top surface of the etching region and an end surface of each of the one or more conductive connections in the conductive connection structure being no greater than the etching depth. The etching depth can be determined based on an etching time.

In some embodiments, depositing the isolating material over the array structure and the conductive connection structure includes: depositing the isolating material between adjacent conductive connections in the conductive connection structure and over the conductive layer in the array structure. The method can further include: after depositing the isolating material over the array structure and the conductive connection structure, polishing a surface of the deposited isolating material.

In some embodiments, the isolating material includes Tetraethyl Orthosilicate (TEOS), and depositing the isolating material can include performing boundary field oxide (BFOX) isolation.

Another aspect of the present disclosure features a semiconductor device, including: an array structure including a conductive layer coupled to a plurality of strings of memory cells; a conductive connection structure positioned separately from the array structure, the conductive connection structure including a plurality of conductive connections; and a conductive pad layer arranged above the array structure and the conductive connection structure, the conductive pad layer including a plurality of conductive pads coupled to a portion of the conductive layer and each of the plurality of conductive connections through corresponding conductive vias. The plurality of conductive connections are separated by an isolating material filled in the conductive connection structure.

In some embodiments, the corresponding conductive vias are separated and isolated by the isolating material filled between the conductive pad layer, the array structure, and the conductive connection structure.

In some embodiments, conductive material is absent between the conductive connection structure and the array structure. In some embodiments, conductive material is absent between the plurality of conductive connections in the conductive connection structure.

In some embodiments, a connection angle between the conductive pad layer and at least one of the respective conductive vias is about 90 degrees.

In some embodiments, the array structure and the conductive connection structure are integrated in a first die. The semiconductor device further can include a second die integrated with the first die, and at least one of the plurality of conductive connections can be coupled to a control circuit in the second die.

In some embodiments, the semiconductor device further includes a cover layer on top of the conductive pad layer. The cover layer can include a plurality of pad openings on top of the plurality of conductive pads in the conductive pad layer, and each of the plurality of conductive pads can be coupled to at least one of the corresponding conductive vias.

A further aspect of the present disclosure features a system including a memory device and a controller coupled to the memory device and configured to control the memory device. The memory device includes: an array structure including a conductive layer coupled to a plurality of strings of memory cells; a conductive connection structure positioned separately from the array structure, the conductive connection structure including a plurality of conductive connections, the plurality of conductive connections being separated by an isolating material filled in the conductive connection structure; and a conductive pad layer arranged above the array structure and the conductive connection structure, the conductive pad layer including a plurality of conductive pads coupled to a portion of the conductive layer and each of the plurality of conductive connections through corresponding conductive vias.

In some embodiments, the memory device further includes: a plurality of conductive interconnections through a cover layer on top of the conductive pad layer to be in contact with the plurality of conductive pads in the conductive pad layer, and each of the plurality of conductive pads is coupled to at least one of the corresponding conductive vias. The controller can be coupled to the memory device through at least one of the plurality of conductive interconnections.

Implementations of the present disclosure can provide one or more of the following technical advantages and/or benefits. For example, in some implementations, as one or more last steps of forming a 3D memory device, a 3D memory array and peripheral circuitry are conductively coupled to conductive pads for coupling out to external components or devices. The techniques implemented herein can manage the conductive connections for the 3D memory device to simplify processing steps, improve etching calibration accuracy, reduce the number of machines to be used, and reduce fabrication cost. For example, the techniques enable to omit a number of process steps (e.g., atomic layer deposition (ALD) oxide deposition, metal remove, etching through surface contacts (TSCs), compared to conventional methods, which can expedite the fabrication process, save fabrication cost, and improve fabrication accuracy and yield.

In some implementations, bottom polysilicon is pre-removed, e.g., from top of a conductive connection structure and an array structure, such that the conductive connection structure and the array structure can be processed using a same mask for patterning and/or depositing to form conductive VIAs and conductive pads together. Moreover, as the bottom polysilicon is removed, there can be no leakage between conductive connections in the conductive connection structure and silicon (Si), which can eliminate through substrate contact (TSC)-Si leakage and burnout issues. Further, processing the conductive connection structure and the array structure together increases a processing window. Thus, the techniques can increase reliability, simplify fabrication process, improve pad coupling input/output (I/O), lower fabrication cost, and improve the performance of the semiconductor devices and systems.

In some implementations, for example, after gate-induced drain leakage (GIDL) loop process is completed, the bottom polysilicon is directly removed to open the conductive connections using buried shallow trench isolation (BSTI) etching process that has low requirement for exposure accuracy in patterning and/or etching, and there is no need to perform backside deep trench ring (BDTI) for isolation. Thus, the techniques can greatly release or increase the processing window and improve pad coupling input/output. As the process does not need BDTI isolation, there is no tungsten (W) remaining issue, which can reduce W dishing.

In some implementations, due to a small aspect ratio of BSTI, TEOS can be used to fill the open area and replace ALD process, and there is no need for etching back and removing Ti residue, which can significantly reduce cost and cycle time. In some implementations, metal such as tungsten W can be filled in trenches for forming conductive VIAs, and aluminum (AI) can be easily deposited on the conductive VIAs for forming conductive pads.

The details of one or more embodiments of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 shows cross-sectional views of a semiconductor device, according to one or embodiments of the present disclosure.

FIG. 2 is a flow chart of an example process of forming a semiconductor device, according to one or embodiments of the present disclosure.

FIGS. 3A-3G show cross-sectional views of structures of a semiconductor device at various stages of a fabrication process, according to one or embodiments of the present disclosure.

FIG. 4 illustrates a block diagram of an example system having one or more semiconductor devices, according to one or embodiments of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

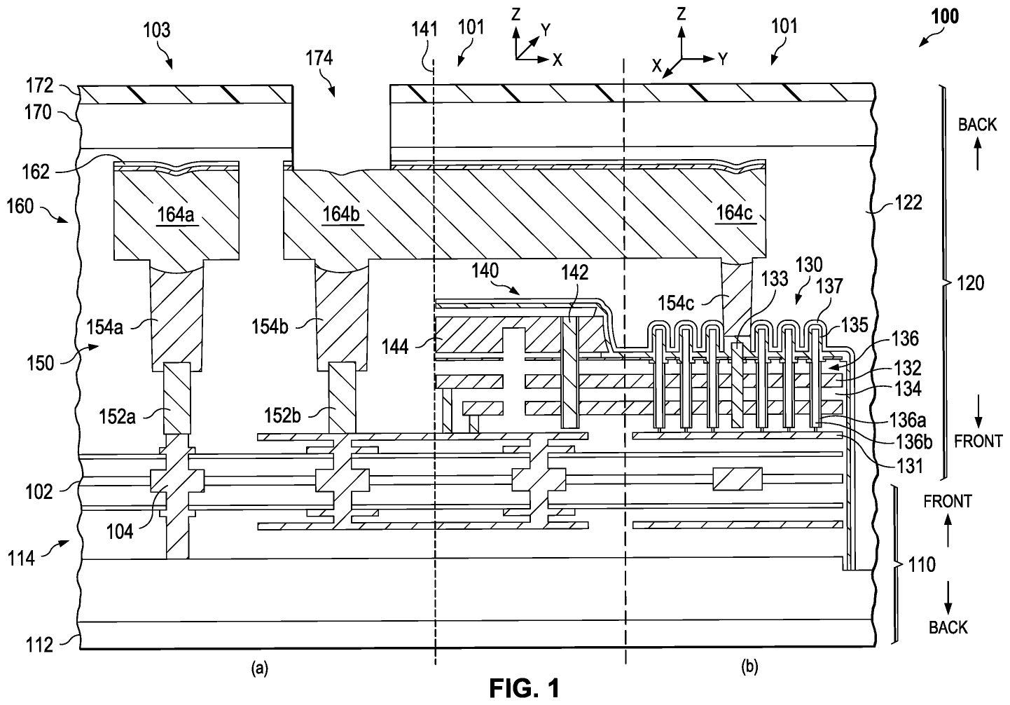

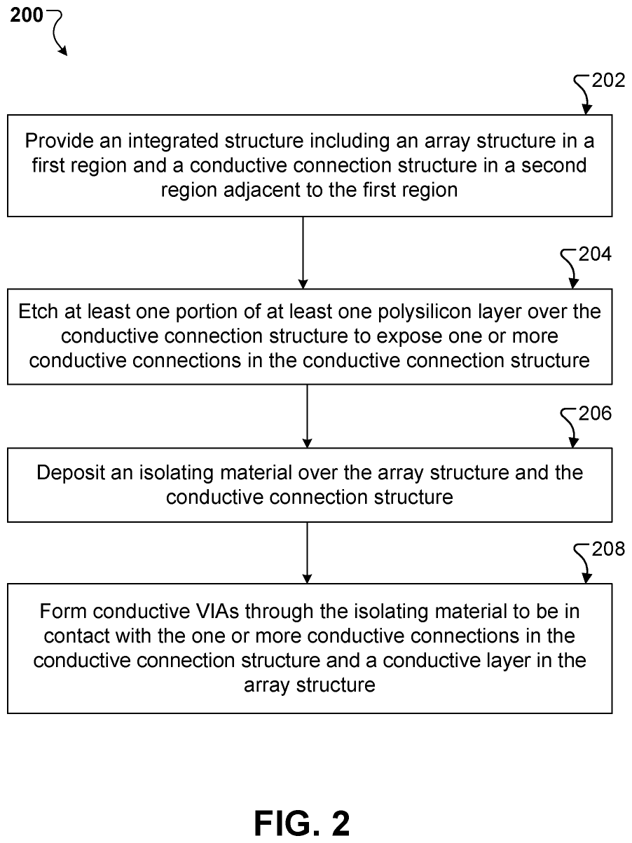

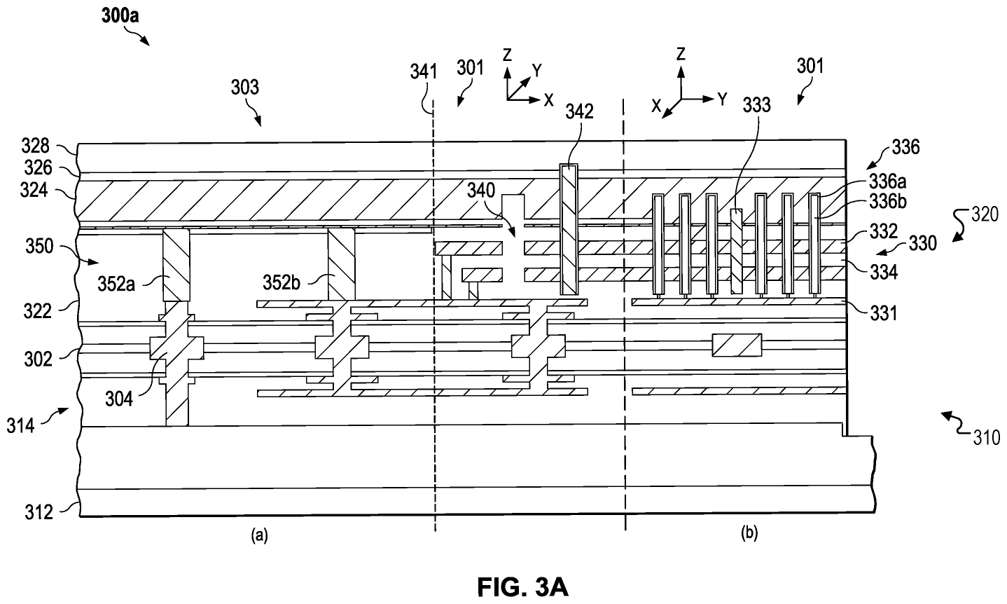

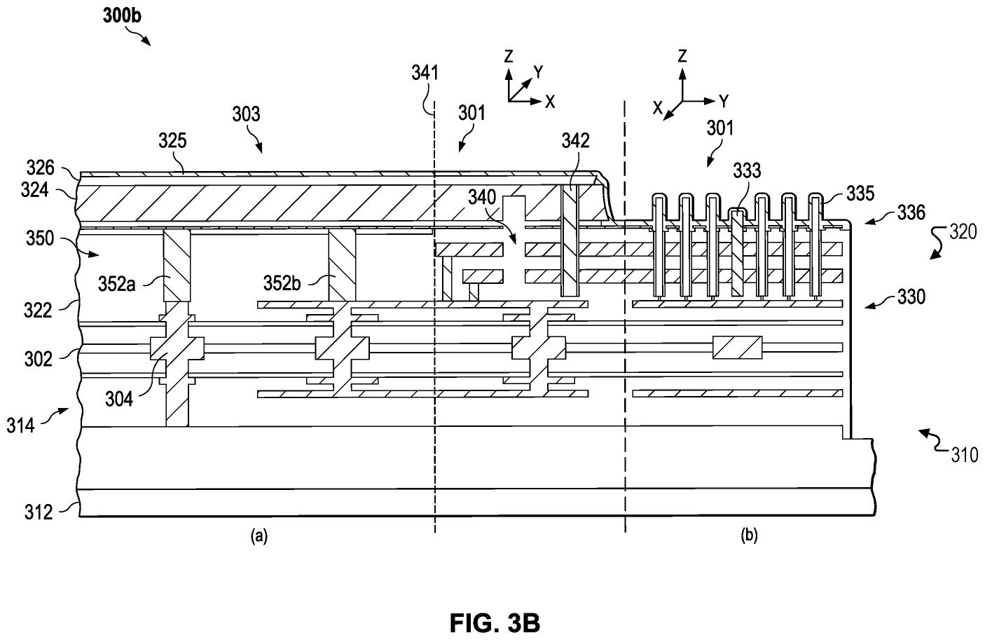

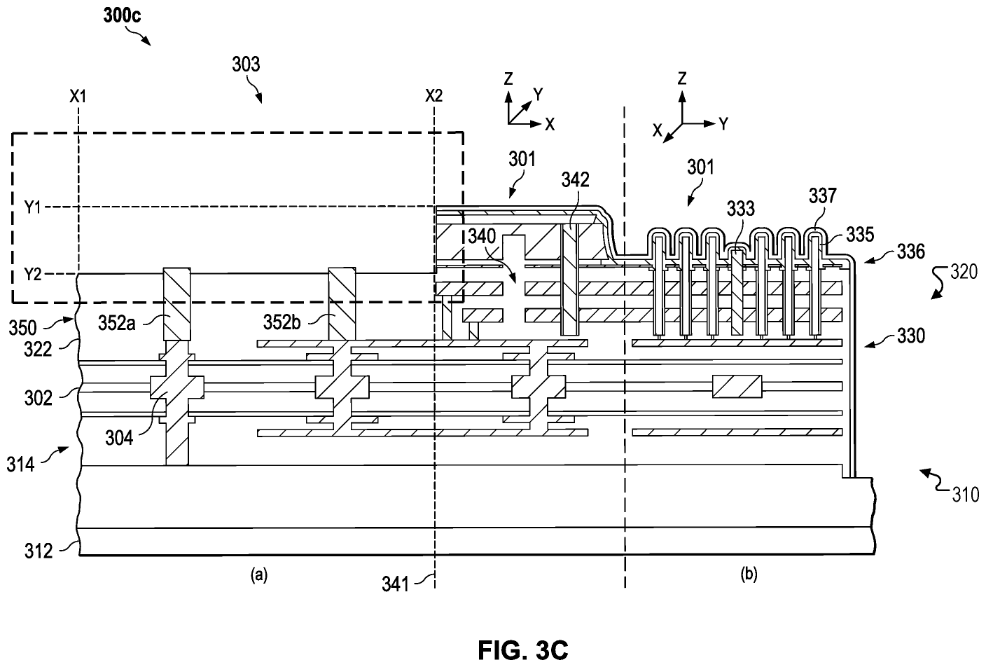

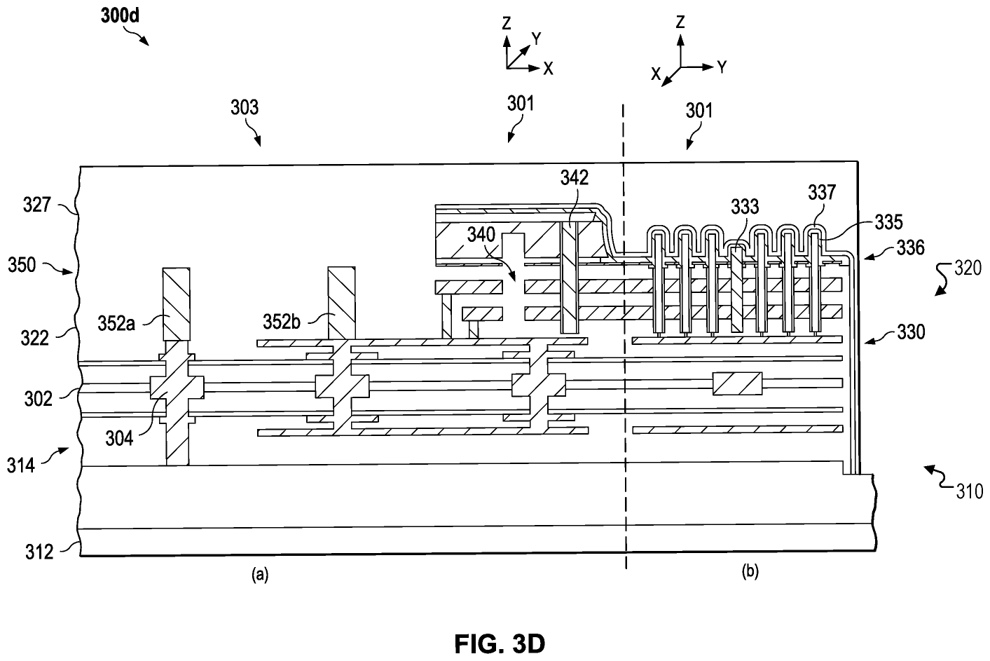

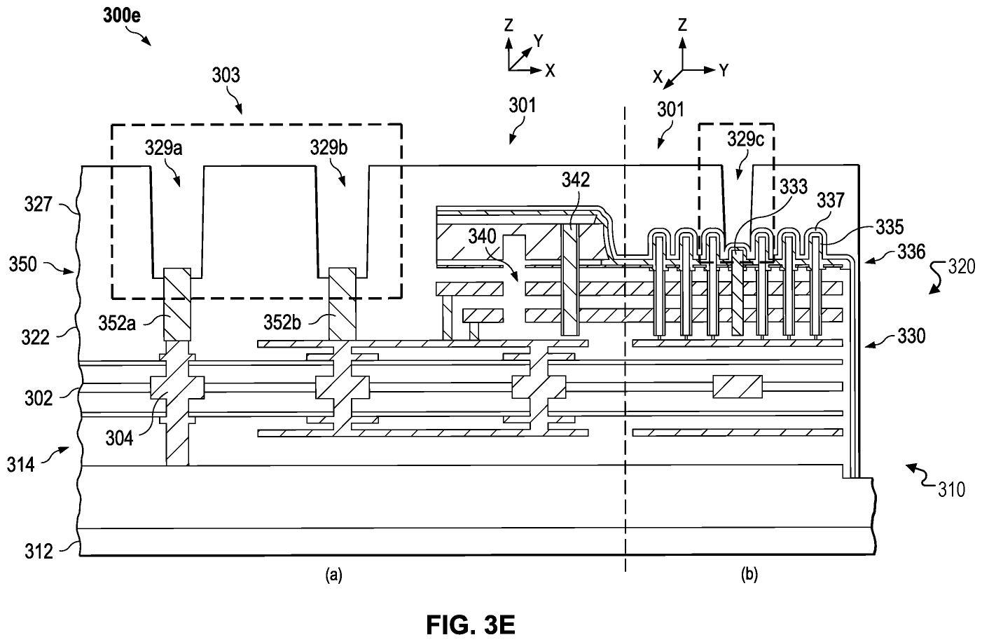

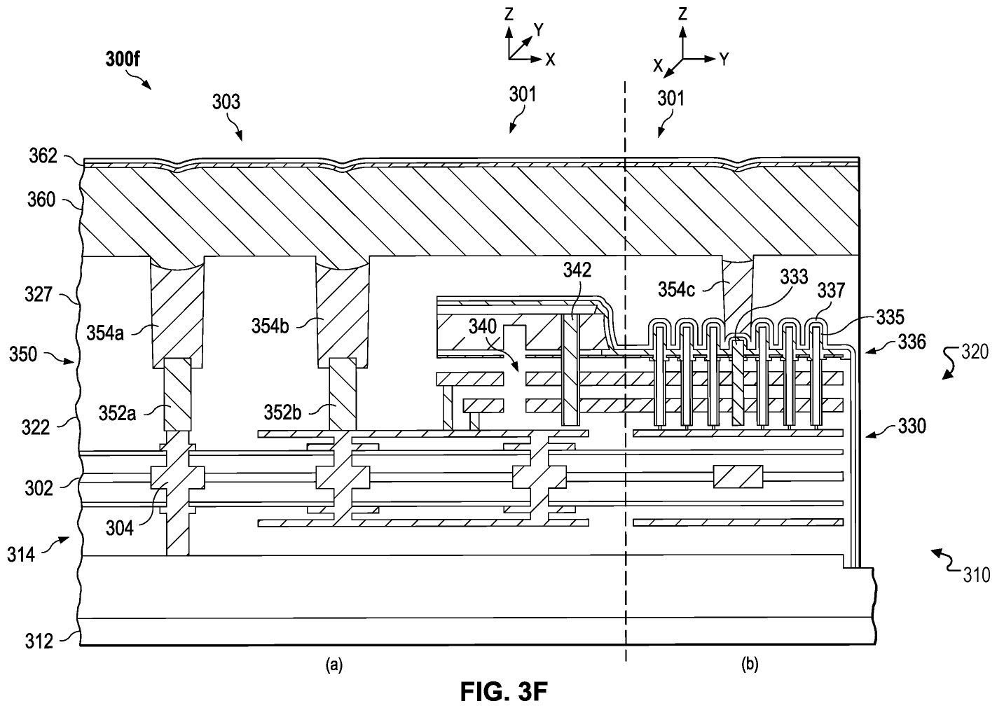

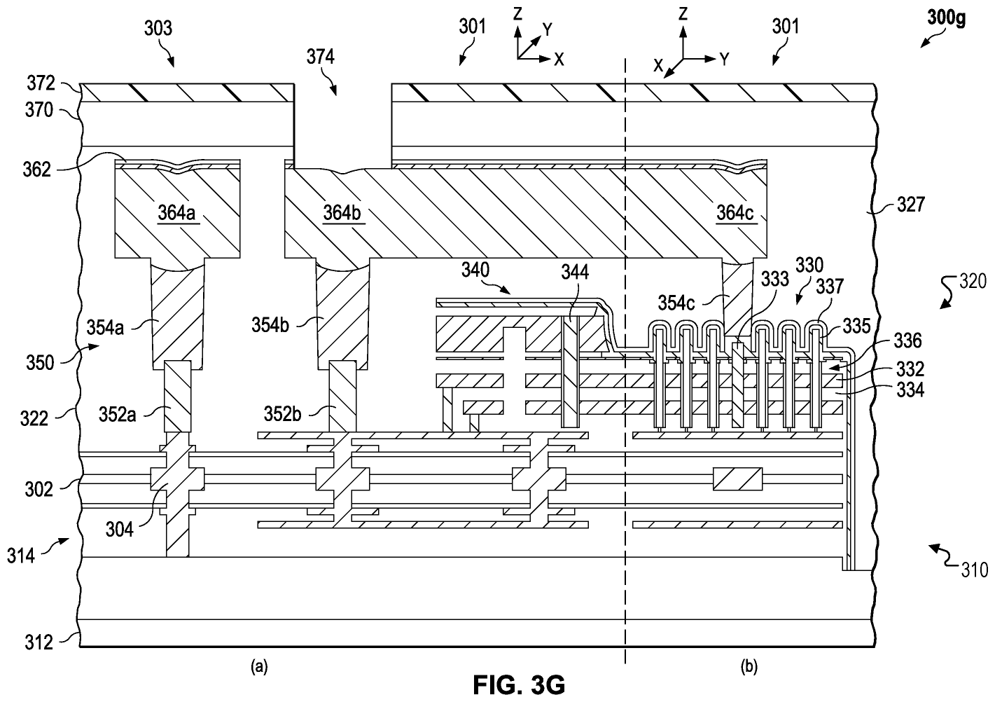

FIG. 1 shows cross-sectional views of a semiconductor device 100, according to one or embodiments of the present disclosure. In some implementations, the semiconductor device 100 is a 3D memory device (e.g., NAND flash memory device). In some implementations, the semiconductor device 100 is an intermediate structure and one or more post-processing steps can be performed on the intermediate structure to form a 3D memory device. The semiconductor device 100 can be formed, e.g., as discussed with further details in FIGS. 2 and FIGS. 3A-3G. Note that, for illustration purposes, FIG. 1 includes two cross-sectional views of the semiconductor device 100 in diagrams (a) and (b), respectively. Diagram (a) shows a cross-sectional view of the semiconductor device 100 in XZ plane, while diagram (b) shows a cross-sectional view of the semiconductor device 100 in YZ plane. The two diagrams (a) and (b) are separated by a dash line in FIG. 1.

In some implementations, as illustrated in FIG. 1, the semiconductor device 100 includes two dies 110 and 120 that are bonded face to face, e.g., through a bonding layer 102 therebetween. In the semiconductor device 100, the die 120 includes an array structure 130 having a memory cell array, which can be referred to as an array die 120, and the die 110 includes peripheral circuitry (or control circuitry) 114, which can be referred to as peripheral die 110. The array structure 130 can be formed on a front side of the array die 120, and the peripheral circuitry 114 can be formed on a front side of the die 110. The array structure 130 and the peripheral circuitry 114 can be conductively coupled to each other by conductive bonding pads 104 (e.g., made of a conductive material like metal) in the bonding layer 102. In some examples, the peripheral circuitry 114 is formed using complementary metal-oxide-semiconductor (CMOS) technology, and the peripheral die 110 is also referred to as CMOS die 110.

In some embodiments, a semiconductor device can include multiple array dies (e.g., the array die 120) and a CMOS die (e.g., the CMOS die 110). The multiple array dies and the CMOS die can be stacked and bonded together. The CMOS die can be respectively coupled to each of the multiple array dies, and can respectively drive each of the multiple array dies to operate in the similar manner as the semiconductor device 100. The semiconductor device 100 can be any suitable device. In some examples, the semiconductor device 100 includes at least a first wafer and a second wafer bonded face to face. The array die 120 can be disposed with other array dies on the first wafer, and the CMOS die 110 can be disposed with other CMOS dies on the second wafer. The first wafer and the second wafer can be bonded together, thus the array dies on the first wafer can be bonded with corresponding CMOS dies on the second wafer. In some examples, the semiconductor device 100 is a chip with at least the array die 120 and the CMOS die 110 bonded together. In an example, the chip is diced from wafers that are bonded together. In another example, the semiconductor device 100 is a semiconductor package that includes one or more semiconductor chips assembled on a package substrate.

In some implementations, the CMOS die 110 includes a substrate 112 and the peripheral circuitry 114 is formed on the substrate 112. The substrate 112 can be any suitable semiconductor substrate having any suitable semiconductor materials, such as monocrystalline, polycrystalline or single crystalline semiconductors. For example, the substrate 112 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. The substrate 112 can be a bulk wafer or an epitaxial layer. For simplicity, a main surface of the substrate 112 is referred to as an XY plane, and a direction perpendicular to the main surface is referred to as Z direction. The peripheral circuitry 114 can include one or more logics and/or circuits including an address decoding circuit, a page buffer circuit or a sense amplifier, data buffers, data I/O circuit, a voltage generator, a control logic, and/or the like.

In some implementations, the array die 120 includes: a) the array structure 130 and a connection structure 140 in a first region 101; and b) a conductive connection structure 150 in a second region 103. The second region 103 can be also referred to as a connection region where one or more conductive connections are arranged for connecting the array structure 130 and/or the connection structure 140 to the peripheral circuitry 114 and/or external components, circuits, and/or devices. The array structure 130 is adjacent to the connection structure 140 in the first region 101. For example, the connection structure 140 can be an extension of the array structure 130. The first region 101 and the second region 103 can be adjacent to each other, e.g., as shown in FIG. 1. A boundary 141 of the connection structure 140 can be considered as a boundary of the first region 101 and/or a boundary of the second region 103.

The array structure 130, the connection structure 140, and the conductive connection structure 150 can be formed in a substrate, e.g., as illustrated with further details in FIG. 3A. The substrate can be a semiconductor substrate, e.g., similar to or same as, the substrate 112. The substrate can be thinned and at least partially removed during forming the semiconductor device 100. For example, the connection structure 140 can include a remaining part 144 of the substrate.

As illustrated in FIG. 1, the array structure 130 can include a plurality of vertical memory cell strings 136, e.g., 3D NAND memory cell strings, along Z direction. The array structure 130 can also include multiple alternating pairs of conductive layers (or word lines) 132 and isolating layers 134. The conductive layer 132 can include a metal material, e.g., Tungsten W, and the isolating layer 134 can include a dielectric material, e.g., silicon oxide, silicon nitride, silicon oxynitride, or any combination thereof. A vertical memory cell string 136 goes through the conductive layers 132 and the isolating layers 134 to be connected to a corresponding bit line 131. The vertical memory cell string 136 can include, in a vertical channel along Z direction, any one of an insulator/trapping or trapping/insulator combination or any one of a poly only or poly/insulator combination. In some examples, the vertical memory cell string 136 includes multiple layers OX/SIN/OX (ONO) 136a that can be formed on an internal surface of the vertical channel and polysilicon 136b that can be filled in a middle of the vertical channel. An external surface of the vertical channel contacts the conductive layers 132, which acts as gates of memory cells of the vertical memory cell string 136.

In some embodiments, the array structure 130 includes a gate line 133 among the plurality of vertical memory cell strings 136. The gate line 133 is configured to separate adjacent memory blocks. During forming the array structure 130, the gate line 133 can be used as a channel for etching sacrifice layers and for filling in a conductive material to form the conductive layers 132. In some embodiments, e.g., as shown in FIG. 1, the gate line 133 has a size (e.g., a diameter or a width) greater than a size (e.g., a diameter or a width) of a memory cell string 136. The array structure 130 can further include a conductive layer 135 formed on top of end surfaces of the plurality of vertical memory cell strings 136 and the gate line 133, e.g., as a common source line (CSL). The common source line can be conductively coupled to an external device (e.g., an external power source or an external control signal), e.g., through a corresponding conductive VIA 154c and a corresponding conductive pad 164c. The conductive layer 135 can be made of polysilicon or metal. A protective layer 137 can be formed on the conductive layer 135. The protective layer 137 can include an isolating material such as a dielectric material such as silicon nitride or Oxide.

In some embodiments, e.g., as shown in FIG. 1, the end surfaces of the plurality of vertical memory cell strings 136 and the gate line 133 form an uneven surface, e.g., an end surface of the gate line 133 can be lower than the end surfaces of the plurality of vertical memory cell strings 136. As the gate line 133 can have a greater size than a vertical memory cell string 136, an end surface of the gate line 133 can have a greater area than an end surface of the vertical memory cell string 136. Thus, the conductive VIA 154c can be formed on a portion of the conductive layer 135 on top of the end surface of the gate line 133, which is easier for patterning and depositing to form the conductive VIA 154c. e.g., as discussed with further details with respect to FIGS. 3E-3F. In some embodiments, the end surfaces of the plurality of vertical memory cell strings 136 and the gate line 133 form an even surface. For example, a layer of a conductive material can be deposited on the end surfaces of plurality of vertical memory cell strings 136 and the end surface of the gate line 133 and then the layer of the conductive material can be polished, e.g., from the uneven surface shown in FIG. 1, to become an even surface. The polished layer of the conductive material forms the conductive layer 135. In this case, the conductive VIA 154c can be formed on any portion of the conductive layer 135 on the even surface.

The connection structure 140 is used to facilitate making conductive connections to, for example, gates of memory cells in the vertical memory cell strings 136, gates of selected transistors, and the like. The gates of the memory cells in the vertical memory cell strings 136 correspond to word lines for a NAND memory architecture. The connection structure 140 is configured to conductively connect the conductive layers 132 (or word lines) to corresponding contact pads (e.g., on a bottom of the connection structure), e.g., by through array contacts (TACs) and/or stair step contacts (SCTs), and further to a control circuitry (e.g., the peripheral circuitry 114 in the CMOS die 110), e.g., through the conductive bonding pads 104.

In some embodiments, the connection structure 140 includes a channel structure 142. The channel structure 142 can be in a shape of a cylinder or a pillar. The channel structure 142 can have a same structure as the vertical memory cell string 136, and the channel structure 142 and the vertical memory cell string 136 can be formed in a same process. In some examples, the channel structure 142 includes multiple layers OX/SIN/OX (ONO) that can be formed on an internal surface of a vertical channel and polysilicon that can be filled in a middle of the vertical channel. The channel structure 142 can be a stop line, and no metal layer is connected to the channel structure 142.

In some embodiments, the array die 120 is configured to include one or more backside metal layers on a back side of the array die 120. The backside metal layers can be used to provide pad structures and/or routing paths. For example, as illustrated in FIG. 1, the array die 120 includes a pad layer 160 having a plurality of conductive pads 164a, 164b, 164c (referred to generally as conductive pads 164 and individually as conductive pad 164). The conductive pads 164 can be separated by an isolating material 122 (e.g., Oxide) in the pad layer 160. The conductive pads 164 can be formed to facilitate attachment of bonding wires that can conductively couple the conductive pads 164 with external components or devices, e.g., power supply, ground, other semiconductor devices, metal wires on printed circuit board (PCB), and/or the like.

In some embodiments, e.g., as illustrated in FIG. 1, the array die 120 includes one or more cover layers on top of the pad layer 160, e.g., an isolating layer 162, a dielectric layer 170 (e.g., made of silicon nitride), and a protection layer 172. A plurality of pad openings 174 can be formed through the one or more cover layers so that the conductive pads 164 can be coupled with the external components by bonding wires through the pad openings 174.

As noted above, in the second region 103 of the array die 120, the conductive connection structure 150 includes a plurality of conductive connections 152a, 152b (referred to generally as conductive connections 152 and individually as conductive connection 152) that are configured to conductively couple to the peripheral circuitry 114 (e.g., through the bonding conductive pads 104) and/or to the conductive layers 132 in the array structure 130 (e.g., through the connection structure 140). As shown in FIG. 1, the conductive connections 152 can be through substrate contacts (TSCs). The conductive connections 152a, 152b can be coupled to corresponding conductive pads 164a, 164b through corresponding conductive VIAs 154a, 154b in the second region 103. The conductive VIAs 154a, 154b, 154c can be referred to generally as conductive VIAs 154 and individually as conductive VIA 154. The conductive VIAs 154a, 154b in the second region 103 and the conductive VIA 154c in the first region 101 can be formed using the same process steps, e.g., as discussed with further details in FIGS. 3D-3F. As discussed with further details below, the bottom polysilicon can be removed from the second region 103, a large processing window can be obtained to form the conductive VIAs 154. In some embodiments, a connection angle between the conductive pad 164 and the conductive VIA 154 is about 90 degrees.

In some embodiments, the conductive VIAs 154 and the conductive pads 164 are made of different materials, e.g., the conductive VIAs 154 can be made of tungsten (W), and the conductive pads 164 can be made of aluminum (Al). The conductive VIAs 154 and the conducive pads 164 can be formed in separate process steps. In some embodiments, the conductive VIAs 154 and the conductive pads 164 are made of a same material, e.g., W, Al, or any suitable conductive material, and the conductive VIAs 154 and the conducive pads 164 can be formed in a same process step.

The array die 120 includes the isolating material 122 filled in different components. For example, the conductive VIAs 154 are separated and isolated by the isolating material 122 filled between the conductive pad layer 160, the array structure 130, and the conductive connection structure 150. Conductive material can be absent between the conductive connection structure 150 and the array structure 130. Conductive material can be absent between the conductive connections 152 in the conductive connection structure 150.

FIG. 2 is a flow chart of an example process 200 of forming a semiconductor device (e.g., the semiconductor device 100 of FIG. 1), according to one or embodiments of the present disclosure. FIGS. 3A-3G show cross-sectional views of structures of a semiconductor device (e.g., the semiconductor device 100 of FIG. 1) at various stages of a fabrication process (e.g., the process 200 of FIG. 2), according to one or more embodiments of the present disclosure. In the following, the process 200 is described with reference to the structures shown in FIGS. 3A-3G. Note that, similar to FIG. 1, for illustration purposes, each of FIGS. 3A-3G includes two cross-sectional views of a corresponding structure in diagrams (a) and (b), respectively. Diagram (a) shows a cross-sectional view of the corresponding structure in XZ plane, while diagram (b) shows a cross-sectional view of the corresponding structure in YZ plane. The two diagrams (a) and (b) are separated by a dash line in each of FIGS. 3A-3G.

At step 202, an integrated structure is provided. The integrated structure can include an array structure in a first region and a conductive connection structure in a second region adjacent to the first region.

For example, as shown in FIG. 3A, an integrated structure 300a can be formed by bonding a peripheral die 310 (e.g., the peripheral die 110 of FIG. 1) and an array die 320 (e.g., the array die 120 of FIG. 1) through a bonding layer 302 (e.g., the bonding layer 102 of FIG. 1) therebetween. The bonding layer 302 can include a plurality of conductive bonding pads 304. The periphery die 310 can be a CMOS die and can include a peripheral circuitry 314 (e.g., the peripheral circuitry 114 of FIG. 1) formed on a substrate 312 (e.g., the substrate 112 of FIG. 1).

Similar to the array die 120 of FIG. 1, the array die 320 can include: a) an array structure 330 (e.g., the array structure 130 of FIG. 1) and a connection structure 340 (e.g., the connection structure 140 of FIG. 1) in a first region 301 (e.g., the first region 101 of FIG. 1); and b) a conductive connection structure 350 (e.g., the conductive connection structure 150 of FIG. 1) in a second region 303 (e.g., the second region 103 of FIG. 1). The connection structure 340 is adjacent to the array structure 330 and can be an extension of the array structure 330. The second region 303 is adjacent to the first region 303 with a boundary 341 (e.g., the boundary 141 of FIG. 1).

The array structure 330, the connection structure 340, and the conductive connection structure 350 can be formed in a substrate, e.g., similar to the substrate 312. The substrate can be any suitable semiconductor substrate having any suitable semiconductor materials, such as monocrystalline, polycrystalline or single crystalline semiconductors. For example, the substrate can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some examples, the substrate includes polysilicon. The substrate can be thinned from a back side of the substrate. The thinned substrate can include a bottom polysilicon layer 324. One or more layers, e.g., an isolating layer 326 (e.g., made of a dielectric material such as Oxide) and a protection layer 328, can be formed on top of the bottom polysilicon layer 324.

Similar to the array structure 130 of FIG. 1, the array structure 330 includes multiple alternating pairs of conductive layer 332 (e.g., the conductive layer 132 of FIG. 1) and isolating layer 334 (e.g., the isolating layer 134 of FIG. 1). The array structure 330 also includes a plurality of vertical memory cell strings 336 (e.g., the vertical memory cell strings 136 of FIG. 1) extending through the conductive layers 332 and the isolating layers 334 to be coupled to a bit line 331 (e.g., the bit line 131 of FIG. 1). Each vertical memory cell string 336 can include multiple layers OX/SIN/OX (ONO) 336a (e.g., ONO 136a of FIG. 1) and polysilicon 336b (e.g., the polysilicon 136b of FIG. 1). The array structure 330 can also include a gate line 333 (e.g., the gate line 133 of FIG. 1) among the plurality of vertical memory cell strings 336. The connection structure 340 can include conductive connections coupled to the conductive layers 332, e.g., by through array contacts (TACs) and conductive pads. The connection structure 340 can include a channel structure 342 (e.g., the channel structure 142 of FIG. 1).

The conductive connection structure 350 is in the second region 303 that can be also referred to as connection region or peripheral region. The conductive connection structure 350 includes a plurality of conductive connections 352a, 352b (referred to generally as conductive connections 352 and individually as conductive connection 352). The conductive connections 352 can be, e.g., the conductive connections 152 of FIG. 1. The conductive connections 352 can be separated and isolated by an isolating material 322 (e.g., Oxide). The conductive connections 352 can be conductively coupled to conductive layers 332 in the array structure 340 and/or the connection structure 340, and coupled to the peripheral circuit 314 in the peripheral die 310.

In some embodiments, at step 202, the integrated structure 300a is provided, and the bottom polysilicon layer 324 is over both the conductive connection structure 350 and the array structure 330. To form a common source line on the array structure 330, the protective layer 328 is first removed, and then first portions of the bottom polysilicon layer 324 and the isolating layer 326 on top of the array structure 330 are etched away to expose the plurality of vertical memory cell strings 336, e.g., on a side of the stop line 342 along X direction. On the other side of the stop line 342, second portions of the bottom polysilicon layer 324 and the isolating layer 326 on the conductive connection structure 350 in the second region 303 and on at least part of the connection structure 340 remain unchanged or unetched. As illustrated in FIG. 3B, a conductive layer (e.g., a source polysilicon layer) 335 can be deposited across the first region 301 and/or the second region 303 to form an integrated structure 300b. The conductive layer 335 can be the conductive layer 135 of FIG. 1 and can be in contact with end surfaces of the plurality of vertical memory cell strings 336 and the gate line 333. In some implementations, an end portion of the vertical memory cell string 336 (e.g., on a back side of the array die 320 that is away from the peripheral die 310) is etched to expose the polysilicon layer 336b of the vertical memory cell strings 336, such that the conductive layer 335 is in contact with the poly layer 336 in the vertical memory strings 336. The end portion of the vertical memory cell string 336 can include the ONO layers 336a.

In some embodiments, at step 202, the integrated structure 300b shown in FIG. 3B is provided, where the first portion of the bottom polysilicon layer 324 is over the conductive connection structure 350, but not over the array structure 330.

At step 204, the at least one portion of the at least one polysilicon layer (e.g., the first portion of the bottom polysilicon layer 324) is etched to expose one or more conductive connections (e.g., the conductive connections 352) in the conductive connection structure (e.g., the conductive connection structure 350).

To protect the array structure 330 and the connection structure 340 from etching, a protective layer 337 (e.g., the protection layer 137 of FIG. 1) is first deposited on top of the array structure 330 and the connection structure 340 in the first region 301, e.g., on top of the conductive layer 335. As shown in a structure 300c of FIG. 3C, an entirety of the first portion of the polysilicon layer 324 within an etching region 327 is etched away to expose end surfaces of the conductive connections 352a, 352b. The etching region 327 can have first and second opposite edges X1, X2 along the X direction. The first edge X1 is extendable to an edge of a plane for the semiconductor device, and the second edge X2 can be extendable to an edge of the second region 303, e.g., the boundary 341. The etching region 327 can have an etching depth from a top surface Y1 to a bottom surface Y2 along the Z direction. The top surface Y1 can be at a same level as a top surface of the connection structure 340 with the conductive layer 335 and the protective layer 337. The bottom surface Y2 can be at a same level or lower than the end surfaces of the conductive connections 352a, 352b, such that the conductive connections 352s, 352b can be exposed for connections. A distance between the top surface Y1 of the etching region 303 and an end surface of each of the conductive connections 352a, 352b in the conductive connection structure 350 is no greater than the etching depth. The etching depth can be determined based on an etching time.

The etching process at step 204 can be performed using a buried shallow trench isolation (BSTI) process to remove the bottom polysilicon layer 324 and the conductive layer 335 (e.g., the source polysilicon layer) in the second region 303. The etching process can be performed by dry etching, e.g., vapor phase etching, reactive-ion etching (RIE), or plasmon etching. The etching process has low requirement for exposure accuracy in patterning and/or etching, and there is no need to perform backside deep trench ring (BDTI) for isolation, which can greatly release or increase a processing window. It can also enable to form conductive VIAs for coupling to conductive pads for inputs/outputs, e.g., as illustrated with details in FIGS. 3D-3G.

At step 206, an isolating material is deposited over the array structure (e.g., the array structure 330) and the conductive connection structure (e.g., the conductive connection structure 350). For example, as shown in FIG. 3D, an isolating material 327 is formed on the structure 300c to obtain a structure 300d, where the isolating material 327 can be filled between adjacent conductive connections 352a, 352b in the conductive connection structure 350 and over the conductive layer 335 on the array structure 330.

In some embodiments, the isolating material 327 includes Oxide, which can be deposited by any suitable deposition method such as atomic layer deposition (ALD), chemical vapor deposition (CVD), or physical vapor deposition (PVD). In some embodiments, as BSTI has a smaller depth to width ratio, the isolating material 327 can include Tetraethyl Orthosilicate (TEOS). The TEOS can be deposited by boundary field oxide (BFOX) isolation process, which can replace other deposition methods such as ALD, without etching back and removing residue (e.g., Ti), to thereby decrease fabrication cost and reduce cycle time.

After depositing the isolating material 327 over the array structure 330 and the conductive connection structure 350, a surface of the deposited isolating material 327 or a surface of the structure 300d can be polished, e.g., using Chemical mechanical polishing (CMP) or planarization, to smooth the surface of the structure 300d.

At step 208, conductive VIAs through the isolating material are formed to be in contact with the one or more conductive connections and a conductive layer in the array structure.

As the bottom polysilicon layer 324 on the conductive connection structure 350 and on the array structure 330 are removed, after depositing the isolating material 327 over the array structure 330 and the conductive connection structure 350, e.g., as illustrated in FIG. 3D, a material to be etched (e.g., the isolating material 327) in the conductive connection structure 350 and the array structure 330 is same. Thus, the conductive connection structure 350 and the array structure 330 can be processed together with a same mask in a same process for patterning to form conductive VIAs, which can greatly increase a processing window. Moreover, there is no leakage between the conductive connections 352 and silicon.

For example, as shown in a structure 300e of FIG. 3E, the deposited isolating material 327 can be patterned using a same mask and removed to form trenches 329a, 329b, 329c (referred to generally as trenches 329 and individually as trench 329) in a same etching process to expose the conductive connections 352a, 352b in the conductive connection structure 350 and a portion of the conductive layer 335, e.g., together in the same etching step. The portion of the conductive layer 335 can be on top of the gate line 333 or any other suitable position in the array structure 330. A size of the trench 329c can be smaller than, identical to, or larger than a size of the end surface of the gate line 333. The size of the trench 329c is controlled to be smaller than a space between adjacent vertical memory cell strings 336, so that the vertical memory cell strings 336 are not exposed. Note that a portion of the protective layer 337 on the portion of the conductive layer 335 is also etched away to expose the portion of the conductive layer 335. The etching step can be performed, e.g., by wet etching. The etching depth can be controlled, e.g., by time, to expose the conductive connections 352a, 352b. For example, as illustrated in FIG. 3E, a bottom surface of the trenches 329a, 329b can be at a same level as or lower than an end surface of the conductive connections 352a, 352b, and a bottom surface of the trench 329c can be a top surface of the conductive layer 335, e.g., on the gate line 333.

Then, a conductive material is deposited into the trenches 329 and on the conductive connections 352a, 352b in the conductive connection structure 350 and the portion of the conductive layer 335 on the gate line 333 in the array structure 330 to form conductive VIAs 354a, 354b, 354c (referred to generally as conductive VIAs 354 and individually as conductive VIA 354). The conductive VIAs 354 can be, e.g., the conductive VIAs 154 of FIG. 1. Each of the conductive VIAs 354a, 354b, 354c is coupled to a corresponding one of the conductive connections 352a, 352b and the portion of the conductive layer 335 on the gate line 333. The conductive material can include a metal such as tungsten W. As components and/or structures between the conductive connections 352 and the connection structure 340 are removed by the etching process at step 204, e.g., as illustrated in FIG. 3C, and the isolating material 327 is filled in the first region 301 and the second region 303 (e.g., between the conductive connections 352, the connection structure 340, and the array structure 330), e.g., as illustrated in FIG. 3D, components and/or structures in the first region 301 and the second region 303 (e.g., the conductive connections 352, the connection structure 340, and the array structure 330) can be conductively isolated by the filled isolating material 327. Thus, the process 200 does not need one or more additional processes to form BDTI isolation to isolate the components and/or structures in the first region 301 and the second region 303, such as the conductive connections 352, the connection structure 340, and the array structure 330. Accordingly, there is no tungsten remaining issue, which can reduce tungsten dishing. In some embodiments, the conductive material includes Aluminum (Al).

In some embodiments, the process 200 further includes: depositing a conductive pad layer 360 on the conducive VIAs 354. For example, as shown in a structure 300f of FIG. 3F, the conductive pad layer 360 is formed on a surface of the structure 300e, e.g., on top of the conductive VIAs 354, and to be in contact with the conductive VIAs 354. The conductive pad layer 360 can include a conductive material, e.g., a metal such as Aluminum (Al).

In some embodiments, the conductive VIAs 354 and the conductive pad layer 360 are made of different materials, e.g., the conductive VIAs 354 can be made of tungsten W, and the conductive pad layer 360 can be made of aluminum (Al). The conductive VIAs 354 and the conducive pad layer 360 can be formed in separate process steps. In some embodiments, the conductive VIAs 354 and the conductive pad layer 360 are made of a same material, e.g., tungsten W, aluminum (Al), or any suitable conductive material. The conductive VIAs 354 and the conducive pad layer 360 can be formed in a same process step, e.g., depositing the same material on the structure 300e to fill the trenches 329 until forming the conductive pad layer 360. In such a way, the process 200 can be simplified.

In some embodiments, an isolating layer 362 (e.g., the isolating layer 162 of FIG. 1) is further formed on the conductive pad layer 360, e.g., as shown in a structure 300f of FIG. 3F.

In some embodiments, the process 200 further includes: forming separate conductive pads 364a, 364b, 364c (referred to generally as conductive pads 364 and individually as conductive pad 364) by patterning the conductive pad layer 360. The conductive pads 364 can be, e.g., the conductive pads 164 of FIG. 1. Each conductive pad 364a, 364b, 364c can be respectively coupled to a corresponding conductive VIA 354 that is respectively coupled to a corresponding one of a conductive connection 352 and the portion of the conductive layer 335 on the gate line 333. In some embodiments, the process 200 further includes: filling in an isolating material (e.g., Oxide) between the adjacent conductive pads 364. A surface of the deposited isolating material can be polished, e.g., by using CMP.

In some embodiments, the process 200 further includes: depositing one or more layers (e.g., a dielectric layer 370 and a protective layer 372) over the conductive pad layer 360. The dielectric layer 370 (e.g., the dielectric layer 170 of FIG. 1) and the protective layer 372 (e.g., the protective layer 172 of FIG. 1) can be sequentially formed on the structure 300f, e.g., after the isolating material is filled between adjacent conductive pads 364.

In some embodiments, as illustrated in FIG. 3G, one or more pad openings 374 (e.g., the pad openings 174 of FIG. 1) are formed through the protective layer 372 and the dielectric layer 370 to expose one or more corresponding conductive pads 364, such that the one or more conductive pads 364 can be coupled with one or more external components by bonding wires through the one or more pad openings 174, e.g., power supply, ground, other semiconductor devices, metal wires on printed circuit board (PCB), and/or the like. Accordingly, the peripheral circuitry 314 in the peripheral die 310 and/or the conductive layers 332 in the array die 320 can be conductively coupled to the one or more eternal components. A structure 300g in the FIG. 3G can be same as, or similar to, the semiconductor device 100 of FIG. 1.

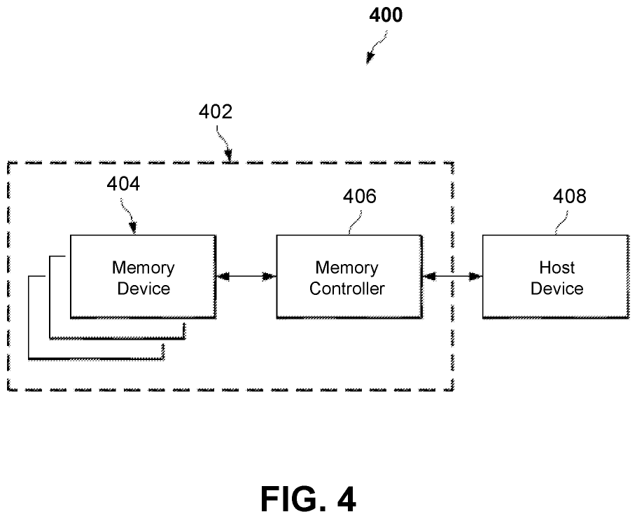

FIG. 4 illustrates a block diagram of a system 400 having one or more semiconductor devices (e.g., memory devices), according to one or more embodiments of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, the system 400 can include a host device 408 and a memory system 402 having one or more 3D memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more 3D memory devices 404.

A 3D memory device 404 can be any 3D memory device disclosed herein, such as 3D memory device depicted in FIGS. 1-3G. In some implementations, a 3D memory device 404 includes a NAND Flash memory. Memory controller 406 (a.k.a., a controller circuit) is coupled to 3D memory device 404 and host device 408. Consistent with implementations of the present disclosure, 3D memory device 404 can include a plurality of conductive interconnections through a cover layer that are in contact with conductive pads in a conductive pad layer, and memory controller 406 can be coupled to 3D memory device 404 through at least one of the plurality of conductive interconnections. Memory controller 406 is configured to control 3D memory device 404. For example, memory controller 406 may be configured to operate a plurality of channel structures via word lines. Memory controller 406 can manage data stored in 3D memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of 3D memory device 404, such as read, erase, and program (or write) operations. Memory controller 406 can also be configured to manage various functions with respect to the data stored or to be stored in 3D memory device 404 including, but not limited to bad-block management, garbage collection, logical-to-physical address conversion, wear leveling, etc. In some implementations, memory controller 406 is further configured to process error correction codes (ECCs) with respect to the data read from or written to 3D memory device 404. Any other suitable functions may be performed by memory controller 406 as well, for example, formatting 3D memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more 3D memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single 3D memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Embodiments of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Embodiments of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other embodiments whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular embodiments of particular inventions. Certain features that are described in this present disclosure in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method comprising:
providing an integrated structure comprising an array structure in a first region and a conductive connection structure in a second region adjacent to the first region, wherein at least one portion of at least one polysilicon layer is over the conductive connection structure;
etching the at least one portion of the at least one polysilicon layer to expose one or more conductive connections in the conductive connection structure;
depositing an isolating material over the array structure and the conductive connection structure; and
forming conductive vertical interconnect accesses (VIAs) through the isolating material to be in contact with the one or more conductive connections and a conductive layer in the array structure.

2. The method of claim 1, wherein forming the conductive VIAs comprises:
etching the isolating material to expose the one or more conductive connections in the conductive connection structure together with a portion of the conductive layer in the array structure; and
depositing a conductive material on the one or more conductive connections in the conductive connection structure and the portion of the conductive layer in the array structure to form the conductive VIAs, wherein each of the conductive VIAs is coupled to a corresponding one of the one or more conductive connections and the portion of the conductive layer.

3. The method of claim 1, further comprising:
depositing a conductive pad layer on the conducive VIAs;
depositing at least one cover layer over the conductive pad layer; and
forming one or more pad openings through the at least one cover layer to expose one or more corresponding portions of the conductive pad layer.

4. The method of claim 3, further comprising depositing a dielectric layer on the conductive pad layer, the dielectric layer being between the conductive pad layer and the at least one cover layer,
wherein forming the one or more pad openings comprises:
etching through the at least one cover layer and the dielectric layer to form the corresponding pad openings.

5. The method of claim 3, wherein the conductive pad layer comprises a first conductive material, and the conductive VIAs comprise a second conductive material different from the first conductive material.

6. The method of claim 1, wherein the at least one polysilicon layer comprises multiple portions, and wherein the at least one portion of the at least one polysilicon layer is a first portion of the at least one polysilicon layer, and a second portion of the at least one polysilicon layer is over the array structure, and
wherein providing the integrated structure comprises:
etching the second portion of the at least one polysilicon layer to expose a plurality of strings of memory cells and a gate line between adjacent groups of strings in the array structure; and
forming the conductive layer across the first region, wherein the conductive layer is in contact with end surfaces of the plurality of strings of memory cells and the gate line.

7. The method of claim 6, wherein the end surfaces of the plurality of strings of memory cells and the gate line form an even surface.

8. The method of claim 6, wherein the end surfaces of the plurality of strings of memory cells and the gate line form an uneven surface.

9. The method of claim 6, wherein forming the conductive VIAs comprises:
forming a conductive VIA through the isolating material to be in contact with a portion of the conductive layer that is over the gate line.

10. The method of claim 1, wherein etching the at least one portion of the at least one polysilicon layer comprises:
etching an entirety of the at least one portion of the at least one polysilicon layer within an etching region,
wherein the first region and the second region are arranged along a first direction, and the one or more conductive connections extend along a second direction perpendicular to the first direction,
wherein the etching region has first and second opposite edges along the first direction, the first edge being extendable to an edge of a plane for the integrated structure, the second edge being extendable to an edge of the second region, and
wherein the etching region has an etching depth from a top surface to a bottom surface along the second direction, a distance between the top surface of the etching region and an end surface of each of the one or more conductive connections in the conductive connection structure being no greater than the etching depth.

11. The method of claim 1, wherein depositing the isolating material over the array structure and the conductive connection structure comprises:
depositing the isolating material between adjacent conductive connections in the conductive connection structure and over the conductive layer in the array structure, and
wherein the method further comprises:
after depositing the isolating material over the array structure and the conductive connection structure, polishing a surface of the deposited isolating material.

12. A semiconductor device, comprising:
an array structure comprising a conductive layer coupled to a plurality of strings of memory cells;
a conductive connection structure positioned separately from the array structure, the conductive connection structure comprising a plurality of conductive connections; and
a conductive pad layer arranged above the array structure and the conductive connection structure, the conductive pad layer comprising a plurality of conductive pads coupled to a portion of the conductive layer and each of the plurality of conductive connections through corresponding conductive vias,
wherein the plurality of conductive connections are separated by an isolating material filled in the conductive connection structure.

13. The semiconductor device of claim 12, wherein the corresponding conductive vias are separated and isolated by the isolating material filled between the conductive pad layer, the array structure, and the conductive connection structure.

14. The semiconductor device of claim 12, wherein conductive material is absent between the conductive connection structure and the array structure.

15. The semiconductor device of claim 12, wherein conductive material is absent between the plurality of conductive connections in the conductive connection structure.

16. The semiconductor device of claim 12, wherein a connection angle between the conductive pad layer and at least one of the respective conductive vias is about 90 degrees.

17. The semiconductor device of claim 12, wherein the array structure and the conductive connection structure are integrated in a first die, and
wherein the semiconductor device further comprises a second die integrated with the first die, and wherein at least one of the plurality of conductive connections is coupled to a control circuit in the second die.

18. The semiconductor device of claim 12, further comprising a cover layer on top of the conductive pad layer,
wherein the cover layer comprises a plurality of pad openings on top of the plurality of conductive pads in the conductive pad layer, and wherein each of the plurality of conductive pads is coupled to at least one of the corresponding conductive vias.

19. A system, comprising:
a memory device comprising:
an array structure comprising a conductive layer coupled to a plurality of strings of memory cells;
a conductive connection structure positioned separately from the array structure, the conductive connection structure comprising a plurality of conductive connections, wherein the plurality of conductive connections are separated by an isolating material filled in the conductive connection structure; and
a conductive pad layer arranged above the array structure and the conductive connection structure, the conductive pad layer comprising a plurality of conductive pads coupled to a portion of the conductive layer and each of the plurality of conductive connections through corresponding conductive vias; and
a controller coupled to the memory device and configured to control the memory device.

20. The system of claim 19, wherein the memory device further comprises:
a plurality of conductive interconnections through a cover layer on top of the conductive pad layer to be in contact with the plurality of conductive pads in the conductive pad layer, and each of the plurality of conductive pads is coupled to at least one of the corresponding conductive vias,
wherein the controller is coupled to the memory device through at least one of the plurality of conductive interconnections.
